(19) United States
(12) Patent Application Publication
(10) Pub. No.: US 2007/0261883 A1
(43) Pub. Date: Nov. 15, 2007

(54) Methods For Improving The Flux Compatibility Of Underfill Formulations

(76) Inventors: Bruce C.B. Chan, Chino Hills, CA (US); Michael George Todd, Anaheim Hills, CA (US); Maurice Earl Edwards, Hacienda Heights, CA (US)

Correspondence Address: LOCTITE CORPORATION, 1001 TROUT BROOK CROSSING, ROCKY HILL, CT, 06067, US

(21) Appl. No.: 10/599,875

(22) PCT Filed: Apr. 12, 2005
(86) PCT No.: PCT/US05/12264

§ 371 Date: Oct. 12, 2006

Related U.S. Application Data
(60) Provisional application No. 60/564,782, filed on Apr. 22, 2004.

(51) Int. Cl. H05K 1/02; B29C 65/00

(52) U.S. Cl. 174/259; 156/598; 156/60

(57) ABSTRACT

In accordance with the present invention, it has been discovered that the addition of one or more cationic catalyst(s), such as onium salts as defined herein, provides improved flux compatibility of underfill formulations in the presence of flux, flux residues and/or reaction products thereof. Accordingly, there are provided methods for improving the flux compatibility of underfill formulations in the presence of flux, flux residues and/or reaction products thereof. In accordance with another embodiment of the present invention, there are provided methods for improving HAST performance of underfill formulations, especially in the presence of flux, flux residues and/or reaction products thereof. In accordance with another embodiment of the present invention, there are provided methods for preparing underfill formulations having improved flux compatibility, especially in the presence of flux, flux residues and/or reaction products thereof. In yet another embodiment of the present invention, there are provided methods for adhesively attaching and/or encapsulating electronic components, especially in the presence of flux, flux residues and/or reaction products thereof. In a further embodiment of the present invention, there are provided articles produced by the above-described processes.

### FIELD OF THE INVENTION

The present invention relates to methods for improving the flux compatibility of underfill formulations, especially in the presence of flux, flux residues and/or reaction products thereof. In a particular aspect, the present invention relates to methods for improving HAST performance of underfill formulations, especially in the presence of flux, flux residues and/or reaction products thereof. In still another aspect, the present invention relates to methods for preparing underfill formulations having improved flux compatibility, especially in the presence of flux, flux residues and/or reaction products thereof. In yet another aspect, the present invention relates to methods for adhesively attaching and/or encapsulating electronic components, especially in the presence of flux, flux residues and/or reaction products thereof. In a further aspect, the present invention relates to articles produced by the above-described processes.

### BACKGROUND OF THE INVENTION

The following discussion of the background of the invention is merely provided to aid the reader in understanding the invention and is not admitted to describe or constitute prior art to the present invention.

Underfill formulations are widely used in the electronics industry to bond various components, such as flip chips, to substrates. Typically, an underfill formulation is handled and applied at room temperature, or heated to an appropriate working temperature, where the formulation flows under the chip by capillary action. It is desirable therefore that underfill materials have good flow properties prior to curing, as well as good performance properties during and after curing, especially in the presence of flux, flux residues and/or reaction products thereof.

Another common use of resins in the electronics industry is as a liquid encapsulant (also referred to as “glob top”), wherein an aliquot of resin material is used to encase (or encapsulate) a component to protect it from certain stresses and from exposure to the environment. To meet the industry's ever-increasing demand for device reliability, materials for encapsulant applications must meet increasingly stringent performance requirements. Such requirements include excellent moisture resistance, ionic purity, low dielectric constant and good thermal properties. In the absence of these properties, especially in the presence of moisture and ionic impurities, corrosion (and ultimately failure of the device) will likely occur at some point during the life of the device.

Underfill and encapsulant formulations are generally quite similar in composition, differing primarily in their end use. Whereas underfill formulations are employed to protect the solder bumps under a chip (and to provide a material of intermediate coefficient of thermal expansion between the chip and the substrate, thereby reducing stress), encapsulant formulations are employed to protect exposed components (e.g., wire bonds and components on the top of a chip), which components would otherwise be exposed to environmental factors such as heat, moisture, particulate matter, and the like.

In any event, both underfill formulations and encapsulant formulations oftentimes suffer from reduced reactivity in the presence of flux or flux residues. “Flux” refers to agents which promote the fusion of metals, and thus are commonly encountered in processes where electronic components are being fabricated. Flux residues refer to derivatives, decomposition products, and the like, of fluxing agents, as a result of such processes as hydrolysis, thermolysis, and the like. Flux or flux residues are undesirable because they are capable of chemically reacting with underfill formulations, potentially changing the characteristics thereof, e.g., reducing the adhesion properties, degrading the mechanical, thermal and/or chemical resistance thereof, and the like. Flux or flux residues can also cause poor flow properties, making handling such as dispensing of the formulation, difficult. In addition, flux or flux residues can lead to a propensity of such formulations to form voids upon cure, which may produce weakness in the resulting bond and/or a gap in the protection afforded by encapsulation.

Accordingly, there remains a need for formulations which display improved performance properties, especially flux compatibility in the presence of flux, flux residues and/or reaction products thereof.

### SUMMARY OF THE INVENTION

In accordance with the present invention, it has been discovered that the addition of one or more cationic catalyst(s), such as onium salts as defined herein, provides improved flux compatibility of underfill formulations in the presence of flux, flux residues and/or reaction products thereof. Accordingly, there are provided methods for improving the flux compatibility of underfill formulations in the presence of flux, flux residues and/or reaction products thereof.

Thus, after a chip is mounted on a circuit board, the space between the chip and the circuit board is filled with a sealing resin (often referred to as underfill sealing) in order to reinforce against stresses caused by thermal cycling. Such underfill encapsulation has gained considerable acceptance in the electronics industry, with epoxy-based resin materials being most commonly used in such applications. Moreover, the expansion coefficients of the underfill sealing can be adjusted, for example, by the addition of low thermal-expansion fillers such as glass or ceramics, thus reducing the level of thermal stress that develops between the substrate and the underfill sealing. The underfill sealing thus provides structural reinforcement, which delocalizes the thermal expansion stress, thereby improving heat shock properties and enhancing the reliability of the structure.

In accordance with another embodiment of the present invention, there are provided methods for improving HAST performance of underfill formulations, especially in the presence of flux, flux residues and/or reaction products thereof. In accordance with yet another embodiment of the present invention, there are provided methods for preparing underfill formulations having improved flux compatibility, especially in the presence of flux, flux residues and/or reaction products thereof. In still another embodiment of the present invention, there are provided methods for adhesively attaching and/or encapsulating electronic components, especially in the presence of flux, flux residues and/or reaction products thereof. In a further embodiment of the present invention, there are provided articles produced by the above-described processes.

### DETAILED DESCRIPTION OF THE INVENTION

In accordance with the present invention, there are provided methods for improving the flux compatibility of underfill formulations in the presence of flux, flux residues and/or reaction products thereof. Invention methods comprise adding an effective amount of one or more cationic catalyst(s) to the underfill formulation.

As readily recognized by those of skill in the art, invention methods can be employed for improving the performance properties of non-fluxing adhesive compositions, such as, for example, underfills, encapsulants, and the like. As employed herein, “non-fluxing adhesive” refers to adhesive compositions that do not have fluxing properties. Stated another way, such compositions generally lack a latent curing agent. Non-fluxing adhesive compositions can be contrasted to fluxing adhesive compositions known in the art which contain a latent curing agent so as to delay cure of the adhesive until after melting of solder associated therewith. Only after the solder is melted does cure of the fluxing adhesive commence. In contrast, non-fluxing adhesive compositions typically have a reduced cure onset temperature, which is not generally compatible with the presence of flux and/or flux residues, absent the treatment contemplated by the present invention.

In accordance with a specific embodiment of the present invention, there are provided methods for improving flux compatibility of an underfill formulation comprising one or more curable resins, filler, coreshell rubber, surfactant and silane, the method comprising adding an effective amount of one or more cationic catalyst(s) to the underfill formulation.

Especially preferred compositions contemplated for treatment according to the methods of the present invention are capillary flow underfills.

As readily recognized by those of skill in the art, a variety of non-fluxing adhesive compositions are suitable for use in the practice of the present invention, e.g., formulations based on such curable resins as epoxy resins, phenolic resins, maleimide resins, (meth)acrylate resins, polyamide resins, polyimide resins, cyanate ester resins, and the like, as well as mixtures of any two or more thereof.

As employed herein, “flux compatibility” refers to the robustness of a formulation to the presence of flux, flux residues and/or reaction products thereof, e.g., the ability to form a strong adhesive bond to a flux contaminated surface. As noted above, the presence of flux often causes reduced reactivity of the respective formulation, as well as poor flow properties (making handling of the formulation difficult), and increased propensity of such formulations to form voids upon cure (producing weakness in the resulting bond and/or a gap in the protection afforded by encapsulation). In contrast to known formulations, invention methods provide formulations that are substantially resistant to the negative effects of flux, and consequently do not suffer from the usual deterioration of performance in the presence thereof.

As employed herein, “flux contaminated” refers to formulations and/or surfaces containing flux or flux residues. As noted above, “flux” refers to agents which promote the fusion of metals, and thus are commonly encountered in processes where electronic components are being fabricated. Flux residues refer to derivatives, decomposition products, and the like, of fluxing agents, as a result of such processes as hydrolysis, thermolysis, and the like. Flux or flux residues are undesirable because they are capable of chemically reacting with underfill formulations, potentially changing the characteristics thereof, e.g., reducing the adhesion properties, degrading the mechanical, thermal and/or chemical resistance thereof, and the like. Flux or flux residues can also cause poor flow properties, making handling such as dispensing of the formulation, difficult. In addition, flux or flux residues can lead to a propensity of such formulations to form voids upon cure, which may produce weakness in the resulting bond and/or a gap in the protection afforded by encapsulation.

As employed herein, “flow properties” of an adhesive formulation refer to the viscosity of a formulation and the ease with which such formulation will flow and wet a flux contaminated surface to provide adhesive bonding thereto. Thus, any reduction in viscosity and/or surface tension of an adhesive formulation to a flux contaminated surface will lead to improved flow properties.

As employed herein, “voiding characteristics” of an invention adhesive formulation refer to the uniformity of an adhesive layer or “glob top” prepared from an invention formulation. Thus, a formulation with excellent voiding properties will cure to produce a substantially uniform, void-free layer, with minimal off-gassing or other disruption of the adhesive layer. As readily recognized by those of skill in the art, a variety of methods can be employed to determine the occurrence of voiding upon cure. For example, the cured surface can be visually inspected for evidence of void formation.

As readily recognized by those of skill in the art, “adding” one or more cationic catalyst(s) to an underfill formulation according to the invention can be accomplished in a variety of ways, such as, for example, by blending, mixing, tumbling, extruding, and the like.

Cationic catalyst(s) contemplated for use in the practice of the present invention comprise onium cations and anions containing a complex anion of a metal or metalloid.

Exemplary onium cations include diaryl salts of group VIIa elements; triaryl salts of group VIa elements; other onium salts of group VIa elements; other onium salts which can be activated by ionizing irradiation, and combinations thereof.

Exemplary anions comprising complex anions of a metal or metalloid include BF₄⁻, PF₆⁻, SbF₆⁻, B(C₆F₅)₄⁻, B(C₄H₂(CF₃)₃)₄⁻; and the like, as well as other borate anions such as those described in U.S. Pat. No. 5,468,902 (incorporated herein by reference), and combinations of any two or more thereof.

Exemplary cationic catalyst(s) contemplated for use in the practice of the present invention include diaryliodonium salts, triarylsulfonium salts, diaryliodosonium salts, triarylsulfoxonium salts, dialkylphenacylsulfonium salts, dialkyl(hydroxy dialkylphenyl)sulfonium salts, phosphonium salts, ferrocenium salts, and the like.

Specific examples of diaryliodonium salts are given by the following formula:

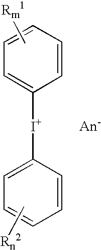

where:
R¹ and R² are each independently selected from the group consisting of alkyl, alkoxy, halogen, and mixtures of any two or more thereof,
n is 0, 1, 2 or 3;
m is 0, 1, 2 or 3; and
An⁻ is an anion. Exemplary anions include hexafluoroarsenate (AsF₆), hexafluoroantimonate (SbF₆), hexafluorophosphate (PF₆), boron tetrafluoride (BF₄), trifluoromethane sulfonate (CF₃SO₃), tetrakis(pentafluorophenylborate) (B[C₆F₅]₄), tetrakis[3,5-bis(trifluoro-methyl)phenyl]borate (B[C₆H₃(CF₃)₂]₄), and the like.

An exemplary iodonium salt is (4-octyloxyphenyl)-phenyliodonium hexafluoroantimonate (R₁═H, R₂═OC8H₁₇, Aⁿ⁻═SbF₈; available, for example, from General Electric Corporation as Aryl Fluoroantimonate Product 479-2092), which has been found to be particularly effective with certain epoxy resins. Additional exemplary iodonium salts include (4-n-decyloxyphenyl)phenyl iodonium hexafluoroantimonate, 4-(2-hydroxytetra decyloxyphenyl)phenyl iodonium hexafluoroantimonate; (4-n-decyloxyphenyl)phenyl-iodonium hexafluoroantimonate; 4-(2-Hydroxytetradecyloxyphenyl)phenyl iodonium hexafluoroantimonate (available, for example, under the tradename Sarcat CD-1012); (4-octyloxy-phenyl)phenyl iodonium hexafluoroantimonate (available, for example, under the tradename UV9392C, GE Silicones), (4-dodecyloxyphenyl)phenyl iodonium hexafluoroantimonate, (4-dodecyloxyphenyl)diphenyl sulfonium hexafluoro-antimonate, di(t-butylphenyl)iodonium triflate, and di(t-butylphenyl)iodonium nonaflate. Additional diaryl iodonium salts such as are described in U.S. Pat. Nos. 5,144,051, 5,079,378 and 5,073,643 are also contemplated for use in the practice of the present invention.

Specific examples of triarylsulfonium salts contemplated for use in the practice of the presented invention are given by the following formulas:

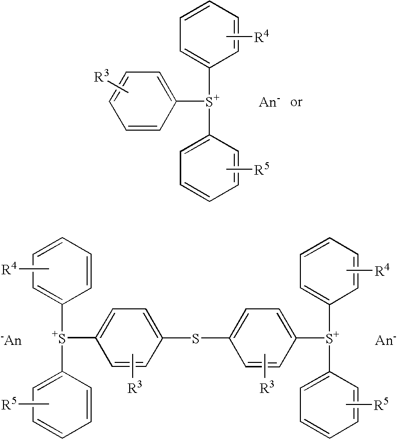

where:
R³, R⁴ and R⁵ are each independently selected from H, alkyl, alkoxy, phenoxy, phenylsulfide, and mixtures of any two or more thereof, and
An⁻ denotes the anion, which may be the same as those of the diaryliodonium salts.

Examples of commercially available triarylsulfonium salts include Cyracure UVI-6974 and Cyracure UVI-6990 (available from Dow). These are mixtures of the triarylsulfonium salts given by the formulas set forth above, where R³ is phenylsulfide and An⁻ is the hexafluoroantimonate and hexafluorophosphate anion, respectively. Degacure Kl-85 (available from Degussa Corporation) and FX-512 (available from 3M Corporation) are both mixtures of triarylsulfonium hexafluorophosphate salts. Other commercially available triarylsulfonium salts contemplated for use in the practice of the present invention include UV691 (available from Dow); triarylsulfonium salt sold as Sarcat CD-1010 by Sartomer Chemical Co., and the like.

Presently preferred diaryliodonium salts include [4-(2-hydroxy-1-tetradecyloxy)-phenyl]phenyliodonium hexafluoroantimonate (available from Polyset Company, Mechanicville, N.Y., as PC-2506; and PC2508). Triarylsulfonium salts, such as the mixture of S,S-diphenyl-4-thiophenoxyphenylsulfonium hexafluoroantimonate and bis(diphenylsulfonio)4,4′-diphenylsulfide bishexafluoroantimonate (as are commercially available from Polyset Company as PC2505). Other dialkylphenacylsulfonium salts contemplated for use in the practice of the present invention include those disclosed in U.S. Pat. No. 6,031,014, the disclosure of which is hereby incorporated by reference herein.

Those of skill in the art can readily determine an effective amount of the one or more cationic catalyst(s) addition for addition to an underfill formulation according to the invention. An effective amount is that amount which is effective to improve one or more of the following performance properties: flux compatibility, flow properties and/or voiding characteristics. Those of skill in the art can readily determine suitable amounts of invention additives to accomplish the desired improvements, particularly after reviewing the examples set forth below.

As readily recognized by those of skill in the art, the amount of one or more cationic catalyst(s) employed in the practice of the present invention can vary widely, typically falling in the range of about 0.1 up to about 10 wt %, based on the weight of the total encapsulation formulation; preferably, the amount of cationic catalyst(s) falls in the range of about 0.2 up to about 5 wt %, based on the weight of the total underfill formulation; with in the range of about 0.5 up to about 2 wt % cationic catalyst(s), based on the weight of the total underfill formulation being presently preferred.

Curable resins contemplated for use in the practice of the present invention include epoxy resin or resins which can be selected from any of a large variety of commercially available materials. Exemplary epoxy resins include those prepared from epoxides of the following structures:

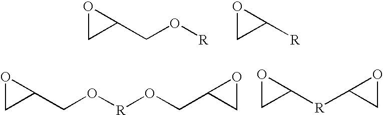

wherein R is a monovalent or bivalent radical. For example, R may be alkyl of up to about 14 carbon atoms, e.g., butyl, pentyl, hexyl, heptyl, octyl, 2-ethyl-hexyl, and the like. Alternatively, R can be aryl (e.g., phenyl) or alkylaryl, such as, for example, cresyl, t-butyl phenyl, nonylphenyl, and the like. R may also be linear or branched alkylene such as, for example, allyl. R can ether be a bivalent linear or branched structure containing the groups —(CH₂CH₂O)ₙ—, —(CH₂CH₂CH₂O)ₙ—, and the like, wherein n may be, for example, up to about 10 or more. Additional epoxy resins contemplated for use in the practice of the present invention include polymers with pendent epoxy or cycloaliphatic epoxide groups.

These materials can optionally be used with commercially available epoxy reactive diluents and functional modifiers. Specific examples of such materials may be found in Handbook of Composites, Edited by George Lubin, Van Nostrand Reinhold Company, Inc., New York, N.Y. (1982), pages 61 to 63, and Shell Chemical Company technical brochure SC-1928-95, HELOXY® Epoxy Functional Modifiers.

Certain of the epoxy materials are either high viscosity liquids or solids at room temperatures. Therefore, it is contemplated that higher viscosity materials may be blended with lower viscosity epoxy materials or with reactive or non-reactive diluents as discussed below in order to achieve the desired viscosity for ease in processing. Heating may be required to achieve the desired flow properties of the uncured formulation but temperatures should not be sufficiently high to cause thermal curing of the epoxy group. Specific blends have been found to have a good overall combination of low viscosity in the uncured states and high glass transition temperature, flexural strength and modulus when cured. One blend which can be mentioned is a high performance semi-solid epoxy such as Tactix 556 with lower viscosity bisphenol A or bis-phenol F based glycidyl ether epoxies such as Tactix 123 or Epon 861, respectively.

Other exemplary epoxy-based formulations contemplated for use in the practice of the present invention include resins prepared from C₄-C₂₈ alkyl mono- and di-glycidyl ethers (e.g., butyl glycidyl ether, 2-ethylhexyl glycidyl ether, butanediol diglycidyl ether, neopentyl glycol diglycidyl ether, and the like); C₂-C₂₈ alkyl- and alkenyl-glycidyl esters; C₁-C₂₈ alkyl-, mono- and poly-phenol glycidyl ethers (e.g., phenyl glycidyl ether, cresyl glycidyl ether, bisphenol A diglycidyl ether, bis-phenol F diglycidyl ether, diglycidyl ortho-phthalate, diglycidyl para-phthalate, hydrogenated diglycidyl ortho-phthalate, and the like), epoxidized novolac resins, 3,4-epoxycyclohexylmethyl-3,4-epoxycyclohexane carboxylate, aniline diglycidyl ether, and the like. Presently preferred epoxy-based formulation contemplated for use in the practice of the present invention include formulations wherein the epoxy component is 1,6-glycidoxypropyl naphthalene, bis-(4-glycidoxyphenol)-isopropane, bis-(4-glycidoxyphenol)methane, and the like. An especially preferred epoxy contemplated for use in the practice of the present invention is 1,6-glycidoxypropyl naphthalene.

Specific examples of epoxy resins contemplated for use in the practice of the present invention include any one or more of the following glycidyl ethers:
(a) Diglycidyl ethers of Bisphenol A of the formula: 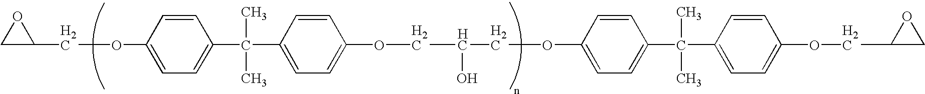
where n=0 to 10; such resins are available from a number of manufacturers such as Shell Chemical Company, Dow Chemical Company, and Ciba Specialty Chemicals in a-variety of molecular weights and viscosities. Examples include: D.E.R. 332, D.E.R. 330, D.E.R. 331, D.E.R. 383, Tactix 123, Tactix 138, and Tactix 177 (Dow™); Epon 825, Epon 826, and Epon 828 (Shell™); and, Araldite GY 6008, Araldite GY 6010, and Araldite GY 2600 (Ciba™);
(b) Diglycidyl ethers of Bis-phenol F and Epoxy Phenol Novolacs of the formula: 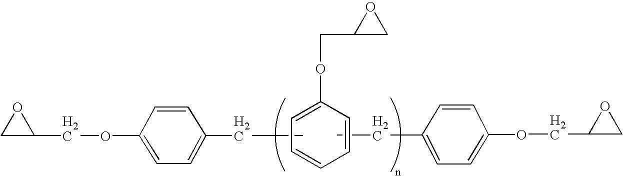
where Diglycidyl ethers of Bis-phenol F, n=0; and Epoxy Phenol Novolacs, n>0; such materials are available from a number of different manufacturers in a variety of molecular weights and viscosities. Examples include: Epon 155, Epon 160, Epon 861 and Epon 862 (Shell™), DEN 431, DEN 436, DEN 438, DEN 439, DEN 444, and Tactix 785 (Dow™), Araldite PY 306, Araldite EPN 1138, Araldite EPN 1139, Araldite EPN 1179, Araldite EPN 1880, Araldite EPN 9880, Araldite GY 281, Araldite GY 282, Araldite GY 285, Araldite GY 308, Araldite LY 9703, Araldite PY 307, and Araldite XD 4995 (Ciba™), and Epalloy 8230, Epalloy 8240, Epalloy 8250, Epalloy 8330, and Epalloy 8350 (CVC Specialty Chemicals™);
(c) Epoxy Cresol Novolacs of the formula: 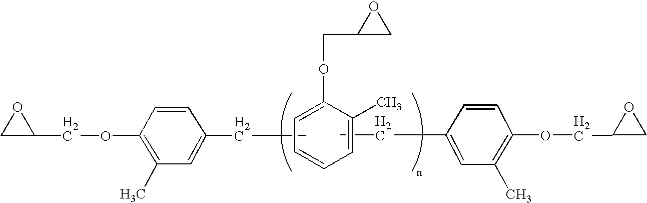
where n>0; epoxy cresol novolacs are available from a number of different manufacturers in a variety of molecular weights and viscosities. Examples include: Epon 164 and Epon RSS-2350 (Shell™), and Araldite ECN 1235, Araldite ECN 1273, Araldite ECN 1280, Araldite ECN 1282, Araldite ECN 1299, Araldite ECN 1400, Araldite ECN 1871, Araldite ECN 1873, Araldite ECN 9511 and Araldite ECN 9699 (Ciba™);
(d) Bisphenol A Epoxy Novolacs of the formula: 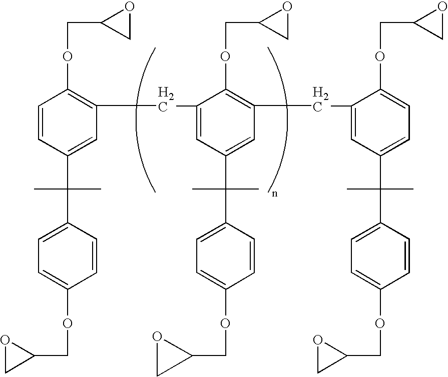
where n=0 to about 2 or more; bisphenol A epoxy novolacs are commercially available in a variety of molecular weights and viscosities as the SU series of resins (Shell Chemical™);
(e) Tetraglycidyl ether of tetrakis (4-hydroxyphenyl)ethane of the formula: 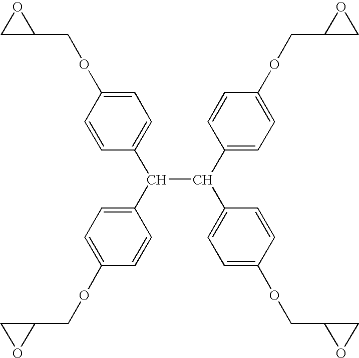
This product is commercially available as Epon 1031 (Shell Chemical™) and Araldite MT 0163 (Ciba™);
(f) Glycidyl ethers of the condensation product of dicyclopentadiene and phenol of the formula: 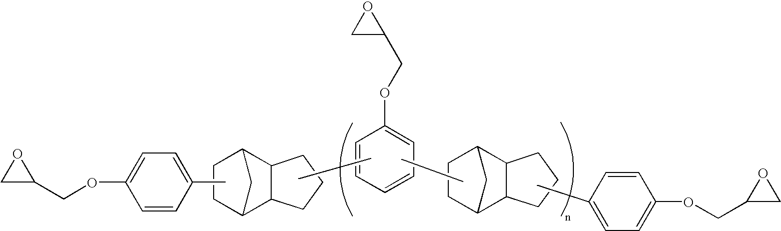
This product is commercially available as Tactix 556 (Dow Chemical™) where n is approximately 0.2;
(g) Triglycidyl ether of tris(hydroxyphenyl)methane of the formula: 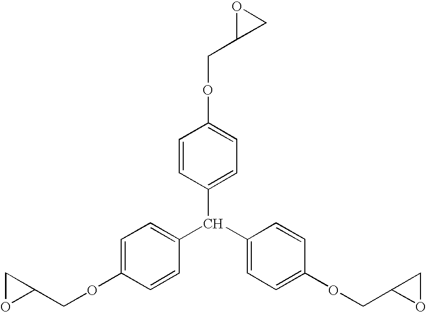
This product is available as Tactix 742 (Dow Chemical™).

The above-described materials can be used alone or as mixtures of any two or more thereof.

Additional examples of epoxy resins contemplated for use in the practice of the present invention include any one or more of the following cycloaliphatic epoxides, either as the main ingredient of the binder formulation or as a diluent, e.g.,
3′,4′-epoxycyclohexylmethyl 3,4-epoxycyclohexanecarboxylate [available as ERL-4221, Cyracure UVR-6110 and LTVR 6105 (Union Carbide Corporation™), Araldite CY-179 (Ciba™), Uvacure 1500 (UCB™) and as Celloxide 2021 (Daicel Chemical Industries Ltd.™)], having the formula: 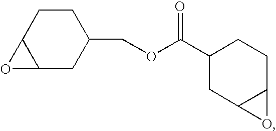
Diglycidyl ester of hexahydrophthalic anhydride [available as CY 184 (Ciba™) ], having the formula: 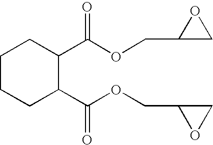
Cyclohexene oxide, having the formula: 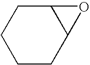
Limonene diepoxide [available as Celloxide 3000 (Daicel Chemical Industries Ltd.™)], having the formula: 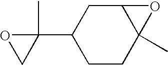
Limonene monoxide, having the structure: 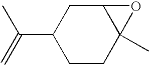
Vinyl cyclohexene dioxide [available as ERL-4206 (Dow Chemical™)], having the structure: 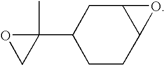
Bis (3,4-epoxycyclohexylmethyl) adipate, having the structure: 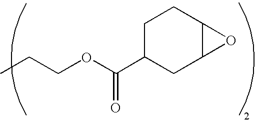
Bis (2,3-epoxy cyclopentyl)ether, having the structure: 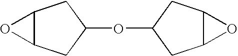
Vinyl cyclohexene oxide [available as Celloxide 2000 (Daicel Chemical Industries Ltd.™)], having the structure: 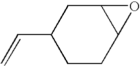
(3,4-epoxy cyclohexene) methyl alcohol [available as ETIB (Daicel Chemical Industries Ltd.™)], having the structure: 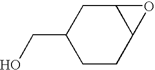
2-(3,4-Epoxycyclohexyl 5,5-spiro-3,4-epoxy)cyclohexane-metadioxane [available as ERL-4234 (Union Carbide Corporation™)] 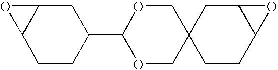
3,4-Epoxycyclohexylmethyl-3′,4′ epoxycyclohexanecarboxylate modified ∈-caprolactone [available in various molecular weights as Celloxide 2081, Celloxide 2083, and Celloxide 2085 (Daicel Chemical Industries Ltd.™)], having the structure: 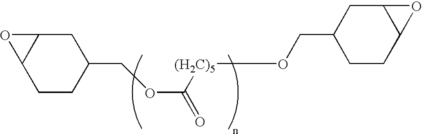
where n>1,
(3,4-Epoxy cyclohexyl)methyl acrylate [available as Cyclomer A-200 (Daicel Chemical Industries Ltd.™)], having the structure: 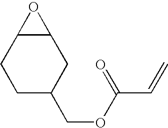
(3,4-Epoxy cyclohexyl)methyl methacrylate [available as Cyclomer M-100 (Daicel Chemical Industries Ltd.™)], having the structure: 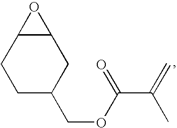
   and the like.

These materials can also be used individually or as mixtures of any two or more thereof.

Epoxy-based formulations can be cured employing a variety of promoters. A presently preferred promoter for such purpose is an anhydride. Exemplary anhydrides contemplated for such purpose include methylhexahydrophthalic anhydride (MEDIA), hexahydrophthalic anhydride (HHPA), tetrahydrophthalic anhydride (THPA), nadic methyl anhydride, benzophenone-tetracarboxylicdianhydride (BTDA), anhydride-terminated polybutadiene, and the like.

Thermal cure of the epoxy resin can be effected through the use of one or more cationic polymerization catalyst(s) with or without the addition of a copper co-catalyst (accelerator). Furthermore, by changing the structures of the materials included with the oligomer and by varying their concentrations, the onset curing temperature and the speed of cure can be adjusted within a wide latitude. Alternatively, curing can be induced by irradiation of the cationic polymerization catalyst/epoxy resin by UV light (or at longer wavelengths as discussed below) or by e-beam. E-beam curing is described in U.S. Pat. Nos. 5,260,349 and 4,654,379. Curing agents are described in U.S. Pat. Nos. 4,842,800, 5,015,675, 5,095,053, and 5,073,643.

As readily recognized by those of skill in the art, epoxy-based formulations are also capable of homopolymerization. Homopolymerizable systems contemplated for use in the practice of the present invention include formulations wherein a homopolymer of the reactive monomer is formed by free radical or cationic polymerization of an epoxy resin, e.g., polymerization of bis-phenol F epoxy resin with 1-benzyl-2-methylimidazole (1-B-2-MZ). As readily recognized by those of skill in the art, such systems can be cured employing any of a variety of catalyst systems, such as, for example, substituted imidazoles, tertiary amines, cationic catalysts, and the like.

Exemplary maleimide resins contemplated for use in the practice of the present invention include resins prepared from compounds comprising the structure:

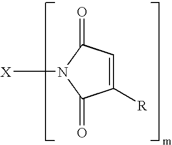

where:
m is an integer between 1 and 6,
each R is independently selected from hydrogen or lower alkyl, and
—X— includes a branched chain alkyl, alkylene, alkylene oxide, ester or amide species having sufficient length and branching to render the maleimide compound a liquid.

As readily recognized by those of skill in the art, X can be any of a variety of moieties, such as, for example, a monovalent or polyvalent radical selected from:
branched hydrocarbyl or substituted branched hydrocarbyl species having in the range of about 12 up to about 500 carbon atoms,
heteroatom-containing branched hydrocarbyl or substituted heteroatom-containing branched hydrocarbyl species having in the range of about 8 up to about 500 carbon atoms,
hydrocarbylene or substituted hydrocarbylene species having in the range of about 12 up to about 500 carbon atoms,
heteroatom-containing hydrocarbylene or substituted heteroatom-containing hydrocarbylene species having in the range of about 8 up to 500 carbon atoms,
polysiloxane,

and the like.

Exemplary (meth)acrylate resins contemplated for use in the practice of the present invention may be prepared from a host of different compounds. As used herein, the terms (meth)acrylic and (meth)acrylate are used synonymously with regard to the monomer and monomer-containing component. The terms (meth)acrylic and (meth)acrylate include acrylic, methacrylic, acrylate and methacrylate. (Meth)acrylates contemplated for use in the practice of the present invention may comprise one or more members selected from a monomer represented by:

1) the formula: 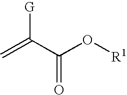
wherein:
   G is hydrogen, halogen, or an alkyl having from 1 to 4 carbon atoms,
   R¹ has from 1 to 16 carbon atoms and is an alkyl, cycloalkyl, alkenyl, cycloalkenyl, alkaryl, aralkyl, or aryl group, optionally substituted or interrupted with silane, silicon, oxygen, halogen, carbonyl, hydroxyl, ester, carboxylic acid, urea, urethane, carbamate, amine, amide, sulfur, sulfonate, or sulfone;

2) urethane acrylates or ureide acrylates represented by the formula: 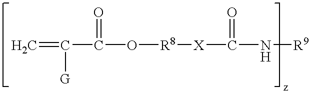
wherein:
   G is hydrogen, halogen, or an alkyl having from 1 to 4 carbon atoms;
   R⁸ denotes a divalent aliphatic, cycloaliphatic, aromatic, or araliphatic group, bound through a carbon atom or carbon atoms thereof indicated at the —O— atom and —X— atom or group;
   X is —O—, —NH—, or —N(alkyl)-, in which the alkyl radical has from 1 to 8 carbon atoms;
   z is 2 to 6; and
   R⁹ is a z-valent cycloaliphatic, aromatic, or araliphatic group bound through a carbon atom or carbon atoms thereof to the one or more NH groups; or

3) a di- or tri-(meth)acrylate selected from polyethylene glycol di(meth)acrylates, bisphenol-A di(meth)acrylates, tetrahydrofurane di(meth)acrylates, hexanediol di(meth)acrylate, trimethylol propane tri(meth)acrylate, and the like, as well as combinations of any two or more thereof.

Suitable polymerizable (meth)acrylate monomers include triethylene glycol dimethacrylate, tripropylene glycol diacrylate, tetraethylene glycol dimethacrylate, diethylene glycol dimethacrylate, 1,4-butanediol diacrylate, 1,6-hexanediol dimethacrylate, pentaerythritol tetraacrylate, trimethylol propane triacrylate, trimethylol propane trimethacrylate, di-pentaerythritol monohydroxypentaacrylate, pentaerythritol triacrylate, bisphenol-A-ethoxylate dimethacrylate, trimethylolpropane ethoxylate triacrylate, trimethylolpropane propoxylate triacrylate, bisphenol-A-diepoxide dimethacrylate, and the like, as well as combinations of any two or more thereof.

Additionally, (meth)acrylate monomers contemplated for use herein include polyethylene glycol di(meth)acrylates, bisphenol-A di(meth)acrylates, tetrahydrofurane (meth)acrylates and di(meth)acrylates, citronellyl acrylate and citronellyl methacrylate, hydroxypropyl (meth)acrylate, hexanediol di(meth)acrylate, trimethylol propane tri(meth)acrylate, tetrahydrodicyclopentadienyl (meth)acrylate, ethoxylated trimethylol propane triacrylate, triethylene glycol acrylate, triethylene glycol methacrylate, and the like, as well as combinations of any two or more thereof.

Of course, (meth)acrylated silicones may also be used, provided the silicone backbone is not so large so as to minimize the effect of (meth)acrylate when cure occurs.

Other acrylates suitable for use herein include the low viscosity acrylates disclosed and claimed in U.S. Pat. No. 6,211,320 (Dershem), the disclosure of which is expressly incorporated herein by reference in its entirety.

Exemplary polyamide resins contemplated for use in the practice of the present invention include polymeric materials with a plurality of amide (—C(O)—NR—) linkages.

Exemplary polyimide resins contemplated for use in the practice of the present invention include polymeric materials with a plurality of imide (—C(O)—NR—C(O)—) linkages.

Exemplary cyanate ester resins contemplated for use in the practice of the present invention include resins prepared from compounds such as those described in U.S. Pat. Nos. 5,358,992, 5,447,988, 5,489,641, 5,646,241, 5,718,941 and 5,753,748, each of which are hereby incorporated by reference herein in their entirety. For instance, cyanate esters useful as a component in the inventive compositions may be chosen from dicyanatobenzenes, tricyanatobenzenes, dicyanatonaphthalenes, tricyanatonaphthalenes, dicyanato-biphenyl, bis(cyanatophenyl)methanes and alkyl derivatives thereof, bis(dihalocyanatophenyl)propanes, bis(cyanatophenyl)ethers, bis(cyanatophenyl)sulfides, bis(cyanatophenyl)propanes, tris(cyanatophenyl)phosphites, tris(cyanatophenyl)phosphates, bis(halocyanatophenyl)methanes, cyanated novolac, bis[cyanatophenyl-(methylethylidene)]benzene, cyanated bisphenol-terminated thermoplastic oligomers, and the like, as well as combinations of any two or more thereof.

More specifically contemplated for use herein are aryl compounds having at least one cyanate ester group on each molecule; such compounds may generally be represented by the formula Ar(OCN)m, where Ar is an aromatic radical and m is an integer from 2 to 5. The aromatic radical Ar should contain at least 6 carbon atoms, and may be derived, for example, from aromatic hydrocarbons, such as phenyl, biphenyl, naphthalene, anthracene, or the like. The aromatic radical Ar may also be derived from a polynuclear aromatic hydrocarbon in which at least two aromatic rings are attached to each other through a bridging group. Also included are aromatic radicals derived from novolac-type phenolic resins—i.e., cyanate esters of these phenolic resins. Ar may also contain further ring-attached, non-reactive substituents.

Examples of such cyanate esters include, for instance, 1,3-dicyanatobenzene; 1,4-dicyanatobenzene; 1,3,5-tricyanatobenzene; 1,3-, 1,4-, 1,6-, 1,8-, 2,6- or 2,7-dicyanatonaphthalene; 1,3,6-tricyanatonaphthalene; 4,4′-dicyanato-biphenyl; bis(4-cyanatophenyl)methane and 3,3′,5,5′-tetramethyl bis(4-cyanatophenyl)methane; 2,2-bis(3,5-dichloro-4-cyanatophenyl)propane; 2,2-bis(3,5-dibromo-4-dicyanatophenyl)propane; bis(4-cyanatophenyl)ether; bis(4-cyanatophenyl)sulfide; 2,2-bis(4-cyanatophenyl)propane; tris(4-cyanatophenyl)-phosphite; tris(4-cyanatophenyl)phosphate; bis(3-chloro-4-cyanatophenyl)methane; cyanated novolac; 1,3-bis[4-cyanatophenyl-1-(methylethylidene)]benzene, cyanated bisphenol-terminated polycarbonate or other thermoplastic oligomer, and the like, as well as combinations of any two or more thereof.

Particularly desirable cyanate esters contemplated for use herein are available commercially from Ciba Specialty Chemicals, Tarrytown, N.Y. under the tradename “AROCY” [1,1-di(4-cyanatophenylethane)]. The structures of three “AROCY” cyanate esters are shown below:

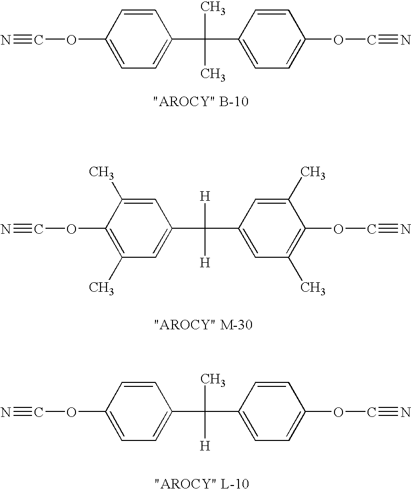

The curable compositions contemplated for use in the practice of the present invention may include an inorganic filler material. Fillers traditionally employed for the preparation of underfill formulations having electrically insulating properties are non-conductive materials such as, for example, inorganic fillers, such as aluminum nitride, boron nitride, alumina, silicon dioxide, and the like, and polymeric fillers, such as teflon, polyolefins, and the like. Those of skill in the art readily recognize that the desirability of including filler in the underfill formulations employed in the practice of the present invention will depend on the end use contemplated therefor. Thus, for example, when preparing formulations for use as an underfill formulation, it is desirable to include substantial quantities of a filler such as silica therein (typically in the range of about 10 up to 75 wt % filler, relative to the weight of the base formulation).

Any suitable inorganic filler material may be used in the practice of the present invention. Specific examples of suitable inorganic filler materials include, but are not limited to, materials constructed of or containing reinforcing silicas, aluminum oxide, silicon nitride, aluminum nitride, silica-coated aluminum nitride and boron nitride. When the inorganic filler material and/or other additives are included in the curable composition, they are independently included in an amount of at least 0.1 wt %, often times at least 0.5 wt % and typically at least 1 wt % and not more than 70 wt %, often times not more than 35 wt % and typically not more than 20 wt %.

In order to improve the impact resistance, formulations of resins may contain, as a constituent thereof, a rubber-like elastic substance. These rubber-like elastic substances are incorporated into formulations in an amount of 80 wt. % or less. Other formulations use 60 wt. % or less. Still other formulations use 5 to 50 wt. %. Amounts of more than 80 wt. % may cause poor solvent resistance and decreased modulus of elasticity.

Examples of the rubber-like substance include natural rubber, polybutadiene, polyisoprene, polyisobutylene, neoprene, polysulfide rubber, thiol rubber, acryl rubber, urethane rubber, silicone rubber, epichlorohydrin rubber, a styrene-butadiene block copolymer (SBR), a hydrogenated styrene-butadiene block copolymer (SEB, SBEC), a styrene-butadiene-styrene block copolymer (SBS), a hydrogenated styrene-butadiene-styrene block copolymer (SEBS), a styrene-isoprene block copolymer (SIR), a hydrogenated styrene-isoprene block copolymer (SEP), a styrene-isoprene-styrene copolymer (SIS), a hydrogenated styrene-isoprene-styrene block copolymer (SEPS), ethylene-propylene rubber (EPM), or ethylene-propylene-diene rubber (EPDM).

Examples of the rubber-like substance also includes coreshell type granular elastic substances such as butadiene-acrylonitrile-styrene coreshell rubber (ABS), methyl methacrylate-butadiene-styrene coreshell rubber (MBS), methyl methacrylate-butyl acrylate-styrene coreshell rubber (MAS), octyl acrylate-butadiene-styrene coreshell rubber (MAES), alkyl acrylate-butadiene-acrylonitrile-styrene coreshell rubber (AABS), butadiene-styrene coreshell rubber (SBR), or siloxane-containing coreshell rubber such as methyl methacrylate-butyl acrylate-siloxane coreshell rubber, and modified rubber thereof. These elastic substances may be used singly or in combination of two or more species.

Surfactants may be utilized in underfill formulations to aid in the prevention of process voiding during the flip-chip bonding process and subsequent solder joint reflow and material curing. Various surfactants which may be utilized include organic acrylic polymers, silicones, polyoxyethylene/polyoxypropylene block copolymers, ethylene diamine based polyoxyethylene/polyoxypropylene block copolymers, polyol-based polyoxyalkylenes, fatty alcohol-based polyoxyalkylenes, fatty alcohol polyoxyalkylene alkyl ethers and mixtures thereof. In addition, coupling agents, polymeric modifiers and other ingredients may also be added as desired.

A component which can optionally and advantageously be included in the formulations of the present invention are surface tension reducing agents. These agents are used to reduce the contact angle at the bonding surfaces. The surface tension reducing agent may be a surfactant. Among the suitable surfactants are TWFEN® (available from ICI, Wilmington, Del.), potassium perfluoroalkyl sulfonates, and the like. When present, the surface tension reducing additive is preferably added in amounts in the range of about 0.1 wt % up to about 1 wt %, based on the total weight of formulation.

An example of another component that is optionally added to compositions contemplated for use in the practice of the present invention is an adhesion promoter which has the ability to enhance adhesive to metal bonding. Suitable adhesion promoters include organo silanes (silane) and titanates. A suitable organosilane is 6040, 3-glycidoxy-propyltrimethoxysilane (available from Dow Corning Corp., Midland, Mich.). A suitable titanate is LICA 38, neopentyl (diallyl)oxy, tri(diooctyl)pyro-phosphatotitinate (available from Kenrich Petro Chemicals, Inc., Bayonne, N.J.). The adhesion promoter is preferably added in amounts of from about 0.1 wt % to about 1 wt % based on the total weight of formulation.

In addition, adhesion promoters, such as the silanes, glycidoxypropyl trimethoxysilane (commercially available from OSI under the trade designation A-187), γ-amino propyl triethoxysilane (commercially available from OSI under the trade designation A-1100) or a trimethoxysilyl propylated isocyanurate (commercially available from OSI under the trade name SILQUEST, such as Y-11597), may be used.

Those of skill in the art recognize that formulations employed for the preparation of many different electronic packages would benefit from employing an effective amount of one or more cationic catalyst(s) as contemplated herein. Examples of electronic packages contemplated for preparation employing invention compositions include ball grid arrays, super ball grid analysis. IC memory cards, chip carriers, hybrid circuits, chip-on-board, multi-chip modules, pin grid arrays, chip scale packages (CSPs), flip chip, discretes, and the like. Additional assemblies contemplated for preparation employing invention compositions include bonding packages to board, bonding daughter boards to board assemblies, bonding boards to housings, bonding heatsinks to assemblies, and the like, especially when such compositions are subjected to flux contamination.

In accordance with another embodiment of the present invention, there are provided methods for improving HAST performance of an underfill formulation in the presence of flux, flux residues and/or reaction products thereof, the method comprising adding an amount of one or more cationic catalyst(s) to the underfill formulation effective to improve the HAST performance thereof.

In accordance with yet another embodiment of the present invention, there are provided methods for preparing an underfill formulation having improved flux compatibility in the presence of flux, flux residues and/or reaction products thereof, the method comprising adding an amount of one or more cationic catalyst(s) to the underfill formulation effective to improve the flux compatibility thereof.

In one aspect of the present invention, the cationic catalyst is added to the underfill formulation at elevated temperatures. Typical elevated temperatures contemplated for use in the practice of the present invention fall in the range of about 30° C. up to about 150° C.

In another aspect of the present invention, the curable resin, cationic catalyst, optional filler, coreshell rubber, surfactant, and silane form a homogeneous solution. In a presently preferred embodiment of the present invention, the homogeneous solution comprises bis-phenol F epoxy resin, a cycloaliphatic epoxy resin, a silica filler, a coreshell rubber in bis-phenol F epoxy resin, a surfactant, a silane, and a cationic catalyst.

In a particular aspect of the present invention, the homogeneous solution comprises:

| | | |
|---|---|---|
| bis-phenol F epoxy resin | 20 to | 60%; |
| a cycloaliphatic epoxy resin | 5 to | 60%; |
| silica filler | 0 to | 75%; |
| coreshell rubber in bis-phenol F epoxy resin | 0 to | 20%; |
| a surfactant | 0 to | 1%; |
| a silane | 0.1 to | 3%; |
| a cationic catalyst | 1 to | 3%; and |
| a copper co-catalyst | 0.05 to | 1%. |

In a particularly preferred aspect of the present invention, the homogeneous solution comprises:

| | |
|---|---|
| bis-phenol F epoxy resin | 27.8%; |
| a cycloaliphatic epoxy resin | 12.5%; |
| silica filler | 50.0%; |
| coreshell rubber in bis-phenol F epoxy resin | 7.5%; |
| a surfactant | 0.1%; |
| a silane | 0.5%; |
| a cationic catalyst | 1.5%; and |
| a copper co-catalyst | 0.1%. |

In accordance with another embodiment of the present invention, there are provided methods for encapsulating an electronic component in the presence of flux, flux residues and/or reaction products thereof, the method comprising:

applying a composition comprising one or more curable resins and one or more cationic catalyst(s) to the component, and

curing the composition.

In accordance with still another embodiment of the present invention, there are provided methods for encapsulating an electronic component in the presence of flux, flux residues and/or reaction products thereof, the method comprising curing a composition comprising one or more curable resins and one or more cationic catalyst(s) after application of the composition to the component.

In accordance with a further embodiment of the present invention, there are provided methods for adhesively attaching an electronic component to a circuit board in the presence of flux, flux residues and/or reaction products thereof, the method comprising:

applying a composition comprising one or more curable resins and one or more cationic catalyst(s) between the component and the board, and

curing the composition.

In accordance with a still further embodiment of the present invention, there are provided methods for adhesively attaching an electronic component to a circuit board in the presence of flux, flux residues and/or reaction products thereof, the method comprising curing a composition comprising one or more curable resins and one or more cationic catalyst(s) after application of the composition between the component and the board.

In one aspect, curable compositions contemplated for use in the practice of the present invention provide improved adhesion properties to flux contaminated surfaces, relative to compositions containing no cationic catalyst added thereto. As readily recognized by those of skill in the art, there are numerous methods available to determine adhesion properties of a formulation to facilitate the comparison contemplated above.

In accordance with another embodiment of the present invention, there are provided articles comprising an electronic component, encapsulated in the presence of flux, flux residues and/or reaction products thereof, with a cured aliquot of a composition comprising one or more curable resins and one or more cationic catalyst(s).

In accordance with another embodiment of the present invention, there are provided articles comprising an electronic component adhesively attached to a circuit board in the presence of flux, flux residues and/or reaction products thereof, wherein the electronic component is adhesively attached to the board by a cured aliquot of a composition comprising one or more curable resins and one or more cationic catalyst(s).

The invention will now be described in greater detail by reference to the following non-limiting example.

### EXAMPLE

1-3% cationic catalyst [e.g., UV9392C (General Electric), Uvacure 1600(UCB), PC2506 (Polyset), Sarcat 1012 (Sartomer)] was melted into liquid bis-phenol F epoxy resin at 60-80° C. to form a stable solution. This melt-mix was then transferred to a planetary mixer where bis-phenol F epoxy resin, cycloaliphatic epoxy resin, filler, and other ingredients as summarized below were added and mixed until the combination was homogeneous. The mixture was packaged into syringes and kept frozen at −40° C. until used.

An exemplary formulation is as follows:

| | |
|---|---|
| bis-phenol F epoxy resin | 27.8%; |
| a cycloaliphatic epoxy resin | 12.5%; |
| silica filler | 50.0%; |
| coreshell rubber in bis-phenol F epoxy resin | 7.5%; |
| a surfactant | 0.1%; |
| a silane | 0.5%; |
| a cationic catalyst | 1.5%; and |
| a copper co-catalyst | 0.1%. |

The above-described underfill formulations were tested side-by-side with control formulations lacking the cationic catalyst to determine the effectiveness of the invention methods for improving the performance properties of underfill formulations. Delamination of the underfill from a flip-chip die surface was systematically better after HAST exposure (130° C./85% relative humidity) and PCT (Pressure cooker test, i.e., 2 atm 130° C./100% relative humidity) for the modified formulations of the invention on flux contaminated assemblies.

1. A method for improving flux compatibility of an underfill formulation in the presence of flux, flux residues and/or reaction products thereof, said method comprising adding an effective amount of one or more cationic catalyst(s) to said underfill formulation.

2. The method of claim 1 wherein the underfill formulations comprises one or more curable resins and the one or more cationic catalyst(s).

3. The method of claim 2 wherein the underfill formulation further comprises filler.

4. The method of claim 3 wherein the underfill formulation further comprises coreshell rubber.

5-9. (canceled)

10. The method of claim 2 wherein the underfill formulation further comprises at least one curing agent.

11. The method of claim 1 wherein the cationic catalyst is an onium salt.

12. The method of claim 1 wherein the cationic catalyst is selected from the group consisting of a diaryliodonium salt, a triarylsulfonium salt, a diaryliodosonium salt, a triarylsulfoxonium salt, a dialkylphenacyl-sulfonium salt, a dialkyl(hydroxy dialkylphenyl)sulfonium salt, a phosphonium salt, a ferrocenium salt, and combinations of any two or more thereof.

13. The method of claim 1 wherein the cationic catalyst is a diaryliodonium salt or a triarylsulfonium salt.

14. The method of claim 1 wherein the cationic catalyst is a diaryliodonium salt having the formula: 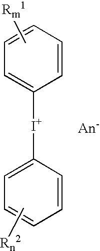
wherein:
R¹ and R² are each independently selected from the group consisting of alkyl, alkoxy and halogen;
m and n are each independently 0-9; and
An⁻ is an anion.

15. The method of claim 14 wherein An⁻ is selected from the group consisting of hexafluoroarsenate (AsF₆) hexafluoroantimonate (SbF₆), hexafluorophosphate (PF₆), boron tetrafluoride (BF₄), trifluoromethane sulfonate (CF₃SO₃), tetrakis (pentafluorophenylborate) (B[C₆F₅]₄), tetrakis[3,5-bis(trifluoro-methyl)phenyl]borate (B[C₆H₃(CF₃)₂]₄), and combinations of any two or more thereof.

16. The method of claim 1 wherein the cationic catalyst is a triarylsulfonium salt having the formulae: 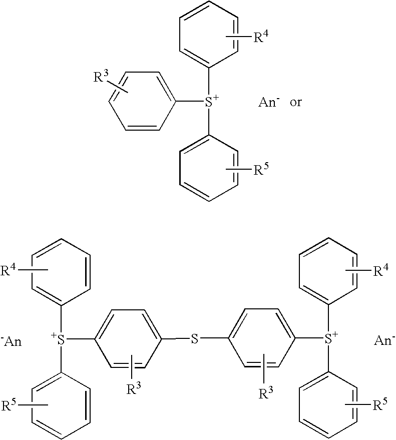
wherein:
R³, R⁴ and R⁵ are each optionally present and are independently selected from the group consisting of alkyl, alkoxy, phenoxy, and phenylsulfide; and
An⁻ is an anion.

17. The method of claim 16 wherein An⁻ is selected from the group consisting of hexafluoroarsenate (AsF₆), hexafluoroantimonate (SbF₆) hexafluorophosphate (PF₆), boron tetrafluoride (BF₄) trifluoromethane sulfonate (CF₃SO₃), tetrakis (pentafluorophenylborate), (B[C₆F₅]₄), tetrakis[3,5-bis(trifluoro-methyl)phenyl]borate (B[C₆H₃(C₆F₃)₂]₄), and combinations of any two or more thereof.

18. The method of claim 1 wherein the cat ionic catalyst is selected from the group consisting of (4-octyloxy-phenyl)phenyliodonium hexafluoroantimonate, [4-(2-hydroxy-1-tetradecyloxy)phenyl]phenyliodonium hexafluoroantimonate, 4-(2-hydroxy-tetradecyloxyphenyl)phenyliodonium hexafluoroantimonate, and combinations of any two or more thereof.

19. The method of claim 18 wherein the cationic catalyst is 0.1-10 wt % of said underfill formulation.

20-21. (canceled)

22. The method of claim 1 wherein the curable resin is selected from the group consisting of epoxy resins, phenol resins, maleimide resins, itaconamide resins, nadimide resins, (meth)acrylate resins, polyamide resins, polyimide resins, cyanate ester resins, and combinations of any two or more thereof.

23. The method of claim 3 wherein the coreshell rubber is selected from the group consisting of butadiene-acrylonitrile-styrene coreshell rubber (ABS), methyl methacrylate-butadiene-styrene coreshell rubber (MBS), methyl methacrylate-butyl acrylate-styrene coreshell rubber (MAS), octyl acrylate-butadiene-styrene coreshell rubber (MABS), alkyl acrylate-butadiene-acrylonitrile-styrene coreshell rubber (AABS), butadiene-styrene coreshell rubber (SBR), methyl methacrylate-butyl acrylate-siloxane coreshell rubber, and combinations of any two or more thereof.

24-27. (canceled)

28. In a method for improving flux compatibility of underfill formulations in the presence of flux, flux residues and/or reaction products thereof, the improvement comprising adding an effective amount of one or more cationic catalyst(s) to the underfill formulation.

29. A method for improving HAST performance of an underfill formulation in the presence of flux, flux residues and/or reaction products thereof, the method comprising adding an amount of one or more cationic catalysts to the underfill formulation effective to improve the MAST performance thereof.

30-33. (canceled)

34. A method for adhesively attaching an electronic component to a circuit board in the presence of flux, flux residues and/or reaction products thereof, the method comprising curing a composition comprising one or more curable resins and one or more cationic catalyst(s) after application of the composition between the component and the board.

35. (canceled)

36. An article comprising an electronic component adhesively attached to a circuit board in the presence of flux flux residues and/or reaction products thereof, wherein the electronic component is adhesively attached to the board by a cured aliquot of a composition comprising one or more curable resins and one or more cationic catalyst(s).
